(19) United States
(12) Patent Application Publication
(10) Pub. No.: US 2007/0122959 A1
(43) Pub. Date: May 31, 2007

(54) Method of forming gate of flash memory device

(75) Inventor: Byoung Ki Lee, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/489,228

(22) Filed: Jul. 19, 2006

(30) Foreign Application Priority Data
Nov. 28, 2005 (KR) 2005-114034

(51) Int. Cl. H01L 21/8234; H01L 21/336

(52) U.S. Cl. 438/197

(57) ABSTRACT

A method of forming a gate of a flash memory device, including the steps of sequentially forming a tunnel oxide film, a first polysilicon layer for a floating gate, a dielectric layer, a second polysilicon layer for a control gate, a tungsten silicide film, and a hard mask film on a semiconductor substrate; etching the hard mask film, the tungsten silicide film, the second polysilicon layer, and a part of the dielectric layer to expose the first polysilicon layer; and etching the exposed first polysilicon layer and the tunnel oxide film to form a gate, wherein during the etch process of the first polysilicon layer, sidewalls of the first polysilicon layer forming the gate are etched to a predetermined width, thereby increasing a gate width ratio between the first polysilicon layer and the second polysilicon layer.

### BACKGROUND

1. Field of the Invention

The invention relates generally to a method of forming a flash memory device, and, more particularly, to a method of forming a gate of a flash memory device, wherein the gate bridge and the gate width ratio between the control gate and the floating gate can be improved, resulting in improved characteristics of the device in a NAND flash device of 70 nanometers to which a self aligned-shallow trench isolation (SA-STI) method is applied.

2. Discussion of Related Art

A flash memory device is a device fabricated by taking the advantages of EPROM having the programming and erasing characteristics and EEPROM having the electrically programming and erasing characteristics. The flash memory device implements a one-bit storage state using one transistor and can perform electrical programming and erase operations.

The flash memory cell generally has a vertical stack type gate structure having a floating gate formed on a silicon substrate. A multi-layer gate structure typically includes one or more tunnel oxide films or dielectric layers, and a control gate formed on and near the floating gate.

A gate formation process of the flash memory device in the related art is briefly described below.

A tunnel oxide film is first formed on a semiconductor substrate. A first polysilicon layer formed of polysilicon, for example, is formed only in the active regions of the semiconductor substrate. A second polysilicon layer is formed on the first polysilicon layer so that it overlaps with a part of an isolation film. The first polysilicon layer and the second polysilicon layer are used as floating gates.

A dielectric layer (in the case of the cell string region), a third polysilicon layer used as a control gate, a tungsten or other conductive metal silicide film, and a hard mask film are formed on the entire structure. The hard mask film, the tungsten silicide film, the third polysilicon layer, the dielectric layer, the second polysilicon layer, the first polysilicon layer, and a part of the tunnel oxide film are sequentially etched, forming a gate.

In the gate formation method of the flash memory device, however, the etch processes for forming the gate must be carried out in different chambers. More particularly, regarding the interface profile between the first polysilicon layer and field oxide, the first polysilicon layer exists below the field oxide due to the slope profile formed in the SA-STI etch process. Accordingly, a problem arises because the first polysilicon layer becomes the source of residue in the gate etch process.

Furthermore, the gate width near the dielectric layer and the gate width ratio near the tunnel oxide film are very important factors in cell characteristics. That is, if the width near the dielectric layer is larger than the width near the tunnel oxide film, the coupling ratio of the cell is increased to improve the cell characteristics.

In the related art, however, the floating gate is etched only using an HBr/O₂-based gas, which is not suitable for the profile. Accordingly, there is a problem in that a high gate width between the control gate and the floating gate cannot be obtained.

### GENERAL DESCRIPTION OF THE INVENTION

In one embodiment, the invention provides a method of forming a gate of a flash memory device, which can improve the gate bridge in NAND flash devices of 70 nanometers or less by performing gate etch processes in the same chamber, and can improve the gate width ratio between a control gate and a floating gate by controlling bias power when etching the floating gate, thereby enhancing the characteristics of the devices.

Accordingly the invention provides a method of forming a gate of a flash memory device, including the steps of sequentially forming a tunnel oxide film, a first polysilicon layer for a floating gate, a dielectric layer, a second polysilicon layer for a control gate, a metal silicide film, and a hard mask film on a semiconductor substrate; etching the hard mask film, the metal silicide film, the second polysilicon layer, and a part of the dielectric layer to expose the first polysilicon layer; and etching the exposed first polysilicon layer and the tunnel oxide film to form a gate, wherein during the etch process of the first polysilicon layer, sidewalls of the first polysilicon layer forming the gate are etched to a predetermined width, thereby increasing a gate width ratio between the first polysilicon layer and the second polysilicon layer.

The etch process of the first polysilicon layer may preferably be performed using ion of CF₄ gas transformed to a plasma state and a low bias power of 80 W to 100 W.

According to another aspect, the invention provides a method of forming a gate of a flash memory device in which a gate etch process is performed in a DPS (decoupled plasma source), DPS+ or DPS II chamber of the type provided by AMAT (applied materials), including the steps of sequentially forming a tunnel oxide film, a first polysilicon layer for a floating gate, a dielectric layer, a second polysilicon layer for a control gate, a metal silicide film, and a hard mask film on a semiconductor substrate; etching the hard mask film and a part of the metal silicide film, wherein a main etch process of the metal silicide film and an over-etch process of the metal silicide film are carried out; performing an etch process of the second polysilicon layer; and etching the dielectric layer, the first polysilicon layer, and the tunnel oxide film, wherein a main etch process of the first polysilicon layer and an over-etch process of the first polysilicon layer are performed.

The main etch process of the tungsten silicide film may preferably be performed using a pressure of 4 mT to 15 mT, a top power of 300 W to 1000 W, a bias power of 30 W to 150 W, NF₃ of 10 SCCM to 30 SCCM, Cl₂ of 10 SCCM to 100 SCCM, O₂ of 1 SCCM to 10 SCCM, N₂ of 10 SCCM to 50 SCCM, and He of 50 SCCM to 200 SCCM.

The main etch process of the metal silicide film may preferably be performed by controlling an etch target utilizing an EPD system mounted in a DPS, DPS+ or DPS II chamber apparatus until the second polysilicon layer of a wide pattern of a peripheral circuit region is exposed.

CF₄ or SF₆ gas may preferably be used instead of the NF₃ gas.

The over-etch process of the tungsten silicide film may preferably be performed using a pressure of 10 mT to 30 mT, a top power of 300 W to 1000 W, a bias power of 20 W to 50 W, Cl₂ of 50 SCCM to 150 SCCM, He of 50 SCCM to 200 SCCM, and N₂ of 1 SCCM to 10 SCCM.

The over-etch process of the tungsten silicide film may preferably be performed by controlling an etch target to correspond 40% to 80% of an EPD (end point detection) time used in the main etch process.

The etch process of the second polysilicon layer may preferably be performed using a pressure of 10 mT to 80 mT, a top power of 300 W to 1000 W, a bias power of 50 W to 200 W, HBr of 50 SCCM to 200 SCCM, O₂ of 0 SCCM to 10 SCCM, and He of 0 SCCM to 200 SCCM.

An etch target of the etch process of the second polysilicon layer may preferably be set to a point at which the second polysilicon layer existing on the dielectric layer in the entire wafer region is stripped.

The main etch process of the first polysilicon layer may preferably be performed using a pressure of 2 mT to 10 mT, a top power of 400 W to 600 W, a bias power of 80 W to 100 W, and CF₄ gas.

The main etch process of the first polysilicon layer may preferably be performed by controlling an etch target utilizing an EPD system mounted in DPS equipment until the tunnel oxide film of a wide pattern of a peripheral circuit region is exposed, wherein an EPD time of 5% to 30% is additionally performed.

The over-etch process of the first polysilicon layer may preferably be performed using a pressure of 10 mT to 80 mT, top power of 300 W to 1000 W, bias power of 50 W to 200 W, HBr of 50 SCCM to 200 SCCM, O₂ of 0 SCCM to 5 SCCM, and He of 0 SCCM to 200 SCCM.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A to 1C are cross-sectional views illustrating a method of forming a gate of a flash memory device according to an embodiment of the invention.

### DETAILED DESCRIPTION OF EMBODIMENTS

The invention will now be described in detail in connection with certain exemplary embodiments with reference to the accompanying drawings.

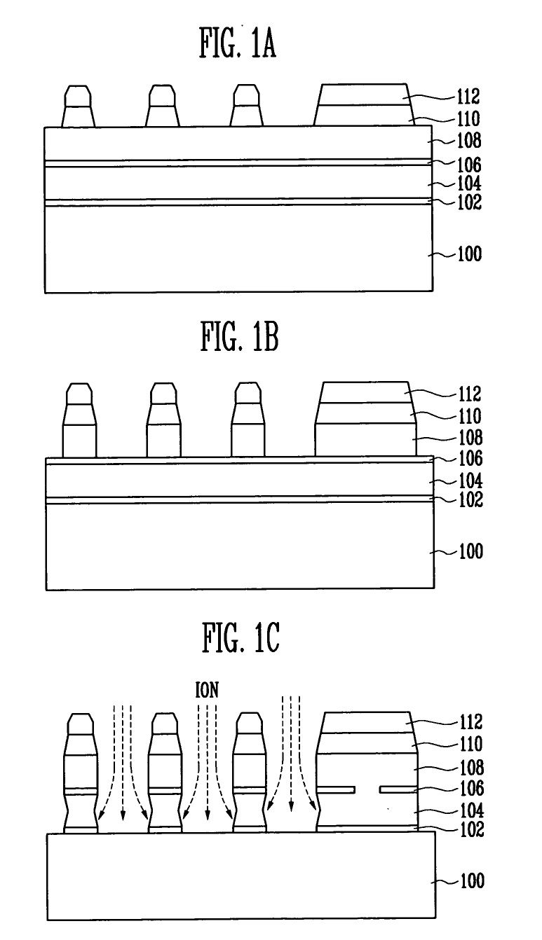

FIGS. 1A to 1C are cross-sectional views illustrating a method of forming a gate of a flash memory device according to an embodiment of the invention.

Referring to FIG. 1A, a tunnel oxide film 102, a first polysilicon layer 104 for a floating gate, a dielectric layer 106, a second polysilicon layer 108 for a control gate, a metal (preferably tungsten) silicide film 110, and a hard mask film 112 are sequentially formed on a semiconductor substrate 100. The dielectric layer 106 has an oxide/nitride/oxide (ONO) structure.

In this case, a polysilicon layer, which is used as a floating gate along with the first polysilicon layer 104, may be formed between the tunnel oxide film 102 and the first polysilicon layer 104 by the SA-STI method. In the embodiment, however, the polysilicon layer is not shown.

A photoresist film pattern is formed on the hard mask film 112. An etch process for forming a gate is performed using the photoresist film pattern as a mask. The gate etch process may be formed in DPS chamber, DPS+ or DPS II, for example. A main etch process of the tungsten silicide film 110 and an over-etch process of the tungsten silicide film 110 are first carried out to expose the second polysilicon layer 108.

The main etch process of the tungsten silicide film 110 may preferably be performed using a pressure of 4 mT to 15 mT, a top power of 300 W to 1000 W, a bias power of 30 SCCM to 150 W, NF₃ of 10 SCCM to 30 SCCM, Cl₂ of 10 SCCM to 100 SCCM, O₂ of 1 SCCM to 10 SCCM, N₂ of 10 SCCM to 50 SCCM, and He of 50 SCCM to 200 SCCM. The NF₃ gas may be replaced with CF₄ or SF₆ gas.

In the main etch process of the tungsten silicide film 110, an etch target is preferably controlled using the EPD system mounted in the DPS equipment and the etch process is stopped when the second polysilicon layer 108 for the control gate of a wide pattern in the peripheral circuit region is exposed.

The over-etch process of the tungsten silicide film 110 is preferably performed using a pressure of 10 mT to 30 mT, a top power of 300 W to 1000 W, a bias power of 20 W to 50 W, Cl₂ of 50 SCCM to 150 SCCM, HE of 50 SCCM to 200 SCCM, and N₂ of 1 SCCM to 10 SCCM.

The over-etch process of the tungsten silicide film 110 may preferably be performed by controlling the etch target to correspond to 40% to 80% of an EPD time used in the main etch process.

Referring to FIG. 1B, the second polysilicon layer 108 exposed through the process of FIG. 1A is etched to expose the dielectric layer 106.

The etch process of the second polysilicon layer 108 may preferably be performed using a pressure of 10 mT to 80 mT, a top power of 300 W to 1000 W, a bias power of 50 W to 200 W, HBr of 50 SCCM to 200 SCCM, O₂ of 0 SCCM to 10 SCCM, and He of 0 SCCM to 200 SCCM.

An etch target of the etch process of the second polysilicon layer 108 is an etch target for stripping the second polysilicon layer 108 existing on the dielectric layer 106 in the entire wafer region.

Referring to FIG. 1C, after the dielectric layer 106 exposed in the process of FIG. 1B is stripped, a main etch process and an over-etch process for stripping the first polysilicon layer 104 are performed.

The main etch process for stripping the first polysilicon layer 104 may preferably be performed using a pressure of 2 to 10 mT, a top power of 400 W to 600 W, a bias power of 80 W to 100 W, and CF₄ gas.

In other words, the sidewalls of the first polysilicon layer 104 forming the gate are etched to a predetermined width preferably using ion of CF₄ gas transformed to a plasma state and a bias power of 100 W or less. Accordingly, the gate width ratio between the first polysilicon layer 104 and the second polysilicon layer 108 can be increased.

Furthermore, CF₄ gas has a very low selectivity ratio of 1:1 to 1:1.2 against oxide of polysilicon. Accordingly, there is an advantage in that a bridge phenomenon can be prevented because polysilicon for the floating gate below the field oxide film is also etched in view of the SA-STI process.

The main etch process of the first polysilicon layer 104 is performed by controlling an etch target utilizing the EPD system mounted in the DPS equipment until the tunnel oxide film 102 of a wide pattern of the peripheral circuit region is exposed. Preferably, in this case, an EPD time of 5% to 30% is additionally performed.

The over-etch process may preferably be performed on the first polysilicon layer 104 using a pressure of 10 mT to 80 mT, a top power of 300 W to 1000 W, a bias power of 50 W to 200 W, HBr of 50 SCCM to 200 SCCM, O₂ of 0 SCCM to 5 SCCM, and He of 0 SCCM to 200 SCCM, thereby exposing the tunnel oxide film 102. The exposed tunnel oxide film 102 is exposed to form a gate.

As described above, according to the invention, the gate bridge can be improved in NAND flash devices of 70 nanometers or less by performing the gate etch processes in the same chamber. Furthermore, the gate width ratio between the second polysilicon layer for the control gate and the first polysilicon layer can be improved by controlling the bias power when etching the floating gate, thereby enhancing the characteristics of the devices.

While the invention has been described in connection with practical exemplary embodiments, the invention is not limited to the disclosed embodiments but, to the contrary, is intended to cover various modifications and equivalent arrangements included within the spirit and scope of the appended claims.

What is claimed is:

1. A method of forming a gate of a flash memory device, the method comprising the steps of:
sequentially forming a tunnel oxide film, a first polysilicon layer for a floating gate, a dielectric layer, a second polysilicon layer for a control gate, a conductive metal silicide film, and a hard mask film on a semiconductor substrate;
etching the hard mask film, the metal silicide film, the second polysilicon layer, and a part of the dielectric layer to expose the first polysilicon layer; and
etching the exposed first polysilicon layer and the tunnel oxide film to form a gate, wherein during the etch process of the first polysilicon layer, sidewalls of the first polysilicon layer forming the gate are etched to a predetermined width, thereby increasing a gate width ratio between the first polysilicon layer and the second polysilicon layer.

2. The method of claim 1, comprising performing the etch process of the first polysilicon layer using ion of CF₄ gas transformed to a plasma state and a low bias power of 80 W to 100 W.

3. The method of claim 1, wherein said metal silicide film is a tungsten silicide film.

4. A method of forming a gate of a flash memory device, in which a gate etch process is performed in a DPS, DPS+ or DPS II chamber, the method comprising the steps of:
sequentially forming a tunnel oxide film, a first polysilicon layer for a floating gate, a dielectric layer, a second polysilicon layer for a control gate, a conductive metal silicide film, and a hard mask film on a semiconductor substrate;
etching the hard mask film and a part of the metal silicide film, comprising carrying out a main etch process of the metal silicide film and an over-etch process of the metal silicide film;
performing an etch process of the second polysilicon layer; and
etching the dielectric layer, the first polysilicon layer, and the tunnel oxide film, comprising carrying out a main etch process of the first polysilicon layer and an over-etch process of the first polysilicon layer.

5. The method of claim 4, comprising performing the main etch process of the metal silicide film using a pressure of 4 mT to 15 mT, a top power of 300 W to 1000 W, a bias power of 30 W to 150 W, NF₃ of 10 SCCM to 30 SCCM, Cl₂ of 10 SCCM to 100 SCCM, O₂ of 1 SCCM to 10 SCCM, N₂ of 10 SCCM to 50 SCCM, and He of 50 SCCM to 200 SCCM.

6. The method of claim 3, comprising performing the main etch process of the metal silicide film by controlling an etch target utilizing an EPD system mounted in a DPS, DPS+ or DPS II chamber apparatus until the second polysilicon layer of a wide pattern of a peripheral circuit region is exposed.

7. The method of claim 3, comprising performing the over-etch process of the metal silicide film using a pressure of 10 mT to 30 mT, a top power of 300 W to 1000 W, a bias power of 20 W to 50 W, Cl₂ of 50 SCCM to 150 SCCM, HE of 50 SCCM to 200 SCCM, and N₂ of 1 SCCM to 10 SCCM.

8. The method of claim 3, comprising performing the over-etch process of the metal silicide film by controlling an etch target to correspond 40% to 80% of an EPD time used in the main etch process.

9. The method of claim 3, comprising performing the etch process of the second polysilicon layer using a pressure of 10 mT to 80 mT, a top power of 300 W to 1000 W, a bias power of 50 W to 200 W, HBr of 50 SCCM to 200 SCCM, O₂ of 0 SCCM to 10 SCCM, and He of 0 SCCM to 200 SCCM.

10. The method of claim 3, comprising setting an etch target of the etch process of the second polysilicon layer to a point at which the second polysilicon layer existing on the dielectric layer in the entire wafer region is stripped.

11. The method of claim 4, comprising performing the main etch process of the first polysilicon layer using a pressure of 2 mT to 10 mT, a top power of 400 W to 600 W, a bias power of 80 W to 100 W, and CF₄ gas.

12. The method of claim 4, comprising performing the main etch process of the first polysilicon layer by controlling an etch target utilizing an EPD system mounted in a DPS equipment until the tunnel oxide film of a wide pattern of a peripheral circuit region is exposed, wherein an EPD time of 5% to 30% is additionally performed.

13. The method of claim 4, comprising performing the over-etch process of the first polysilicon layer using a pressure of 10 mT to 80 mT, top power of 300 W to 1000 W, bias power of 50 W to 200 W, HBr of 50 SCCM to 200 SCCM, ° 2 of 0 SCCM to 5 SCCM, and He of 0 SCCM to 200 SCCM.

14. The method of claim 4, wherein said metal silicide film is a tungsten silicide film.
